(19) United States
(12) Patent Application Publication
(10) Pub. No.: US 2024/0215415 A1
(43) Pub. Date: Jun. 27, 2024

(54) DISPLAY DEVICE

(71) Applicant: Samsung Display Co., Ltd., Yongin-si (KR)

(72) Inventors: MI-RAN JI, Yongin-si (KR); Changwook KIM, Yongin-si (KR)

(21) Appl. No.: 18/368,016

(22) Filed: Sep. 14, 2023

(30) Foreign Application Priority Data
Dec. 21, 2022 (KR) 10-2022-0180705

(51) Int. Cl. H10K 59/80; H10K 59/122; H10K 59/35; H10K 59/40

(52) U.S. Cl. CPC H10K 59/8792; H10K 59/122; H10K 59/35; H10K 59/40; H10K 59/873; H10K 2102/3026

(57) ABSTRACT

Provided is a display device including first light-emitting elements activated in a first operation mode and deactivated in a second operation mode, second light-emitting elements activated in the first and second operation modes, a base substrate including a first region having a first light-emitting region where the first light-emitting elements are disposed and a first non-light-emitting region, and a second region adjacent to the first region and having a second light-emitting region where the second light-emitting elements are disposed and a second non-light-emitting region, an encapsulation layer disposed on the base substrate, a first light-blocking pattern not overlapping the first region and overlapping the second non-light-emitting region, a cover layer covering the first light-blocking pattern, and a second light-blocking pattern disposed on the cover layer and overlapping the first light-blocking pattern, wherein the thickness of the cover layer may be greater than the thickness of the encapsulation layer.

### CROSS-REFERENCE TO RELATED APPLICATIONS

This U.S. non-provisional patent application claims priority under 35 U.S.C. § 119 of Korean Patent Application No. 10-2022-0180705, filed on Dec. 21, 2022, the entire contents of which are hereby incorporated by reference.

### BACKGROUND

The present disclosure herein relates to a display device, and more particularly, to a display device capable of operating in two operation modes.

Electronic apparatuses such as smartphones, tablet computers, laptop computers, car navigation systems, and smart televisions are being developed. Such electronic apparatuses include display devices in order to provide information.

A user requires an image of appropriate quality for the situation in which the image is used. For example, a user requires a brighter image in the outdoors where natural light affects the image viewing, and for a display device in which personal information is read, a user requires an image with a narrow viewing angle.

### SUMMARY

The present disclosure provides a display device capable of preventing leakage of light at a particular viewing angle.

An embodiment of the inventive concept provides a display device including first light-emitting elements, second light-emitting elements, a base substrate, an encapsulation layer, at least one insulation layer, a cover layer, and a second light-blocking pattern. The first light-emitting elements are activated in a first operation mode and deactivated in a second operation mode. The second light-emitting elements are activated in the first operation mode and activated in the second operation mode. The base substrate includes a first region and a second region adjacent to the first region, the first region having a first light-emitting region and a first non-light-emitting region, the first light-emitting elements being disposed in the first light-emitting region, the second region having a second light-emitting region and a second non-light-emitting region, the second light-emitting elements being disposed in the second light-emitting region. The encapsulation layer is disposed on the base substrate and covers the first light-emitting elements and the second light-emitting elements. The at least one insulation layer is disposed on the encapsulation layer. The first light-blocking pattern is disposed on the insulation layer, and does not overlap the first region and overlaps the second non-light-emitting region. The cover layer is disposed on the insulation layer and covers the first light-blocking pattern. The second light-blocking pattern is disposed on the cover layer and overlaps the first light-blocking pattern. A thickness of the cover layer may be greater than a thickness of the encapsulation layer.

In an embodiment, the thickness of the cover layer may be equal to or greater than about 10 μm and equal to or less than about 20 μm.

In an embodiment, the thickness of the encapsulation layer may be equal to or greater than about 6 μm and equal to or less than about 12 μm.

In an embodiment, the display device may further include a sensing electrode disposed on the insulation layer, and overlapping the first non-light-emitting region of the first region and the second non-light-emitting region of the second region, and the sensing electrode may be disposed on a same layer as the first light-blocking pattern.

In an embodiment, the first light-blocking pattern may cover a portion of the sensing electrode overlapping the second region.

In an embodiment, the display device may further include a protective layer disposed on the insulation layer and the sensing electrode and including an inorganic material, and a portion of the protective layer may be disposed between the sensing electrode and the first light-blocking pattern.

In an embodiment, the second light-emitting region may include a first element region in which a first light-emitting element configured to provide a first-color light is disposed, a second element region in which a second light-emitting element configured to provide a second-color light is disposed, and a third element region in which a third light-emitting element configured to provide a third-color light is disposed, and each of the first to third light-emitting elements may include a plurality of sub-light-emitting elements.

In an embodiment, the display device may further include a first pixel-defining layer which is disposed on the base substrate, and in which openings are defined, and each of the first to third light-emitting elements may include a first electrode, a second electrode, and a light-emitting layer disposed between the first electrode and the second electrode, and the openings of the first pixel-defining layer may expose at least a portion of the first electrodes of each of the first to third light-emitting elements.

In an embodiment, the display device may further include a second pixel-defining layer which is disposed on the first electrodes exposed by the openings, and which overlaps the second non-light-emitting region.

In an embodiment, at least one of the encapsulation layer and the cover layer may include an organic material.

In an embodiment, a first line width of the first light-blocking pattern may be greater than a second line width of the second light-blocking pattern.

In an embodiment, the display device may further include an anti-reflection layer disposed on the second light-blocking pattern.

In an embodiment of the inventive concept, a display device includes a base substrate, a light-emitting element, an organic layer, at least one insulation layer, a first light-blocking pattern, a cover layer, and a second light-blocking pattern. The base substrate includes a light-emitting region and a non-light-emitting region. The light-emitting element is disposed on the base substrate. The organic layer is disposed as a single layer on the light-emitting element. The at least one insulation layer is disposed on the organic layer. The first light-blocking pattern is disposed on the insulation layer, and overlaps the non-light-emitting region. The cover layer is disposed on the insulation layer, and covers the first light-blocking pattern. The second light-blocking pattern is disposed on the cover layer and overlaps the first light-blocking pattern. A thickness of the cover layer may be greater than a thickness of the organic layer.

In an embodiment, the thickness of the cover layer may be equal to or greater than about 10 μm and equal to or less than about 20 μm.

In an embodiment, the thickness of the organic layer may be equal to or greater than about 6 μm and equal to or less than about 12 μm.

In an embodiment, the display device may further include a sensing electrode disposed on the insulation layer, and overlapping the non-light-emitting region, and the sensing electrode may be disposed on a same layer as the first light-blocking pattern.

In an embodiment, the display device may further include a protective layer disposed on the insulation layer and the sensing electrode, and including an inorganic material, and a portion of the protective layer may be disposed between the sensing electrode and the first light-blocking pattern.

In an embodiment, the light-emitting region may include a first element region in which a first light-emitting element configured to provide a first-color light is disposed, a second element region in which a second light-emitting element configured to provide a second-color light is disposed, and a third element region in which a third light-emitting element configured to provide a third-color light is disposed, and each of the first to third light-emitting elements may include a plurality of sub-light-emitting elements.

In an embodiment, the first light-blocking pattern may be in contact with the sensing electrode.

In an embodiment, the organic layer and the cover layer may each include an organic material.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept.

FIG. 1 is a perspective view of an electronic apparatus according to an embodiment of the inventive concept.

FIG. 2 is an exploded perspective view illustrating a partial configuration of an electronic apparatus according to an embodiment of the inventive concept.

FIG. 3 is a cross-sectional view of a display device according to an embodiment of the inventive concept.

FIG. 4 is an enlarged plan view of a region AA of FIG. 2 according to an embodiment of the inventive concept.

FIG. 5A is a cross-sectional view taken along line I-I′ of FIG. 4 according to an embodiment of the inventive concept.

FIG. 5B is a cross-sectional view taken along line II-II′ of FIG. 4 according to an embodiment of the inventive concept.

FIG. 6A is an enlarged plan view of the region AA of FIG. 2 in a first operation mode according to an embodiment of the inventive concept.

FIG. 6B is an enlarged plan view of the region AA of FIG. 2 in a second operation mode according to an embodiment of the inventive concept.

FIG. 7 is a plan view of an input sensor according to an embodiment of the inventive concept.

FIG. 8 is an enlarged plan view of a region BB of FIG. 7 according to an embodiment of the inventive concept.

FIG. 9 is an enlarged plan view of the region BB of FIG. 7 according to an embodiment of the inventive concept.

FIG. 10 is an enlarged plan view of the region BB of FIG. 7 according to an embodiment of the inventive concept.

FIG. 11 is a cross-sectional view taken along line III-III′ of FIGS. 9 and 10 according to an embodiment of the inventive concept.

FIG. 12 is a cross-sectional view taken along line IV-IV′ of FIGS. 9 and 10 according to an embodiment of the inventive concept.

FIG. 13 is a cross-sectional view taken along line IV-IV′ of FIGS. 9 and 10 according to an embodiment of the inventive concept.

FIG. 14 is a cross-sectional view taken along line IV-IV′ of FIGS. 9 and 10 according to an embodiment of the inventive concept.

FIG. 15 is an enlarged plan view of the region BB of FIG. 7 according to an embodiment of the inventive concept.

### DETAILED DESCRIPTION

In this specification, it will be understood that when an element (or a region, a layer, a portion, or the like) is referred to as being “on”, “connected to” or “coupled to” another element, it may be directly disposed on, connected or coupled to the other element, or intervening elements may be disposed therebetween.

Like reference numerals or symbols refer to like elements throughout. In the drawings, the thickness, the ratio, and the size of the element are exaggerated for effective description of the technical contents. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the scope of the inventive concept. Similarly, a second element, component, region, layer or section may be termed a first element, component, region, layer or section. As used herein, the singular forms, “a”, “an” and “the” are intended to include the plural forms as well, unless the context clearly indicates otherwise.

Also, terms of “below”, “on lower side”, “above”, “on upper side”, or the like may be used to describe the relationships of the elements illustrated in the drawings. These terms have relative concepts and are described on the basis of the directions indicated in the drawings.

It will be further understood that the terms “includes” and/or “have”, when used in this specification, specify the presence of stated features, integers, steps, operations, elements, components, and/or groups thereof, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the inventive concept will be described with reference to the accompanying drawings.

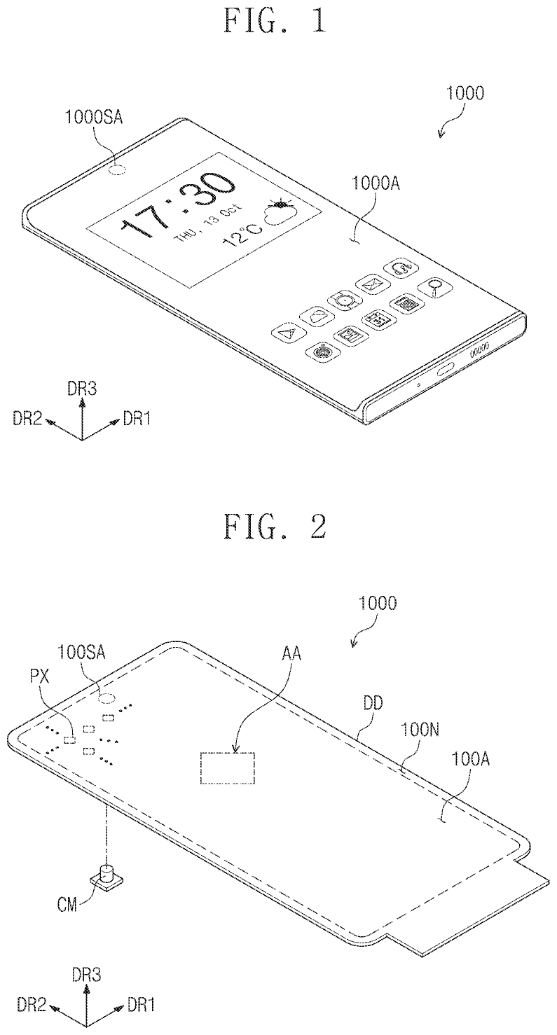

FIG. 1 is a perspective view of an electronic apparatus 1000 according to an embodiment of the inventive concept.

Referring to FIG. 1, the electronic apparatus 1000 may include a display device, and in this embodiment, a smartphone is exemplarily illustrated. However, an embodiment of the inventive concept is not limited thereto, and the electronic apparatus 1000 may be a tablet computer, a monitor, a television, a car navigation system, a game console, or a wearable device. In addition, the electronic apparatus 1000 according to the inventive concept may be an apparatus foldable with respect to a folding axis, or an apparatus in which a display panel is slidable.

The electronic apparatus 1000 may display an image through a display region 1000A. The display region 1000A may include a flat surface defined by a first direction DR1 and a second direction DR2. The display region 1000A may further include curved surfaces respectively bent from at least two sides of the flat surface. However, the shape of the display region 1000A is not limited thereto. For example, the display region 1000A may include only the flat surface, or may further include at least two curved surfaces, for example, four curved surfaces respectively bent from four sides of the flat surface.

A partial region of the display region 1000A may be defined as a sensing region 1000SA. FIG. 1 exemplarily illustrates one sensing region 1000SA, but the number of the sensing region 1000SA is not limited thereto. The sensing region 1000SA may be a part of the display region 1000A, but may have a higher optical signal transmittance than other regions of the display region 1000A. Therefore, an image may be displayed through the sensing region 1000SA, and an optical signal may be provided through the sensing region 1000SA.

The electronic apparatus 1000 may include an electronic module disposed in a region overlapping the sensing region 1000SA. The electronic module may receive an optical signal provided from the outside through the sensing region 1000SA, or output an optical signal through the sensing region 1000SA. For example, the electronic module may be a camera module, a sensor, which measures the distance between an object and a smartphone, such as a proximity sensor, a sensor that perceives a body part of a user, e.g., a fingerprint, iris, or face, or a small-sized lamp that emits light, but an embodiment of the inventive concept is not limited thereto.

The thickness direction of the electronic apparatus 1000 may be a third direction DR3 that is the normal direction of the display region 1000A. Front surfaces (or upper surfaces) and rear surfaces (or lower surfaces) of the members constituting the electronic apparatus 1000 may be defined based on the third direction DR3.

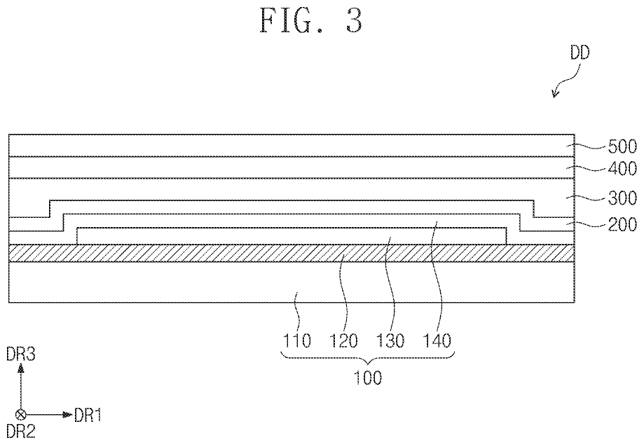

FIG. 2 is a perspective view illustrating a partial configuration of an electronic apparatus 1000 according to an embodiment of the inventive concept.

Referring to FIG. 2, the electronic apparatus 1000 may include a display device DD and a camera module CM. The display device DD may generate an image and detect an external input. The camera module CM is disposed under the display device DD. When the display device DD is defined as a first electronic module included in the electronic apparatus 1000, the camera module CM may be defined as a second electronic module.

A display region 100A and a peripheral region 100N may be included in the display device DD. The display region 100A may correspond to the display region 1000A illustrated in FIG. 1. A partial region of the display device DD may be defined as a sensing region 100SA, and the sensing region 100SA may have a higher transmittance than other regions of the display region 100A. Therefore, the sensing region 100SA may provide natural light from the outside to the camera module CM. The sensing region 100SA is a part of the display region 100A and may thus display an image.

Pixels PX may be disposed in the display region 100A. In the display region 100A, a light-emitting element is disposed, and in the peripheral region 100N, the light-emitting element is not disposed. The pixels PX may be disposed in each of the sensing region 100SA and a main display region 100A. However, the configurations of the pixels PX disposed in the sensing region 100SA may differ from disposed pixels PX in the main display region 100A.

FIG. 3 is a cross-sectional view of a display device DD according to an embodiment of the inventive concept.

Referring to FIG. 3, the display device DD may include a display panel 100, an input sensor 200, a light control layer 300, an anti-reflection layer 400, and a window 500.

The display panel 100 may be a light-emitting-type display panel. For example, the display panel 100 may be an organic light-emitting display panel, an inorganic light-emitting display panel, a micro-LED display panel, a nano-LED display panel, or a quantum-dot display panel. The display panel 100 may include a base substrate 110, a circuit layer 120, a light-emitting element layer 130, and an encapsulation layer 140.

The base substrate 110 may provide a base surface on which the circuit layer 120 is disposed. The base substrate 110 may be a rigid substrate, or a flexible substrate that is bendable, foldable, or rollable. The base substrate 110 may be a glass substrate, a metal substrate, a polymer substrate, or the like. However, an embodiment of the inventive concept is not limited thereto, and the base substrate 110 may include an inorganic layer, an organic layer, or a composite material layer.

The base substrate 110 may have a multi-layer structure. For example, the base substrate 110 may include a first synthetic resin layer, a multi-layer or single-layer inorganic layer, and a second synthetic resin layer disposed on the multi-layer or single-layer inorganic layer. The first and second synthetic resin layers may each include a polyimide-based resin, but an embodiment of the inventive concept is not limited particularly thereto.

The circuit layer 120 may be disposed on the base substrate 110. The circuit layer 120 may include an insulation layer, a semiconductor pattern, a conductive pattern, and a signal line. The circuit layer 120 includes a driving circuit of the pixel PX described in FIG. 2.

The light-emitting element layer 130 may be disposed on the circuit layer 120. The light-emitting element layer 130 may include a light-emitting element of the pixel PX described with reference to FIG. 2. For example, the light-emitting element may include an organic light-emitting material, an inorganic light-emitting material, an organic-inorganic light-emitting material, a quantum dot, a quantum rod, a micro-LED, or a nano-LED.

The encapsulation layer 140 may be disposed on the light-emitting element layer 130. The encapsulation layer 140 may protect the light-emitting element layer 130 from moisture, oxygen, and foreign substances such as dust particles. The encapsulation layer 140 may include at least one inorganic layer. The encapsulation layer 140 may include a stacked structure of an inorganic layer/organic layer/inorganic layer.

The input sensor 200 may be disposed on the display panel 100. The input sensor 200 may detect an external input applied from the outside. The external input may include various types of inputs such as a body part of a user, light, heat, a pen, pressure, or the like.

The input sensor 200 may be formed on the display panel 100 through a continuous process. At this time, the input sensor 200 may be directly disposed on the display panel 100. In this specification, when “component B is directly disposed on component A”, it may be referred to as being no intervening component present therebetween. For example, there may be no adhesive layer disposed between the input sensor 200 and the display panel 100.

The light control layer 300 may be disposed on the input sensor 200. The light control layer 300 may control an emission rate of light provided from the light-emitting element layer 130 according to a region of the display panel 100. The light control layer 300 will be described later.

The anti-reflection layer 400 may be disposed on the light control layer 300. The anti-reflection layer 400 may be bonded to the light control layer 300 by an adhesive layer. The adhesive layer may be a pressure sensitive adhesive film (PSA) or an optically clear adhesive (OCA).

The anti-reflection layer 400 may reduce the reflectance of external light. The anti-reflection layer 400 may include an optical film. The optical film may include a polarizing film. The optical film may further include a retarder film. The retarder film may include at least one of a λ/2 retarder film or a λ/4 retarder film.

The window 500 includes at least one base layer. The base layer may be a glass substrate or a synthetic resin film. The window 500 may have a multi-layer structure. The window 500 may include a thin-film glass substrate and a synthetic resin film disposed on the thin-film glass substrate. The thin-film glass substrate and the synthetic resin film may be bonded to each other by an adhesive layer, and the adhesive layer and the synthetic resin film may be detached from the thin-film glass substrate for the replacement thereof. The window 500 may further include a functional layer disposed on the base layer. The functional layer may include an anti-reflection layer, an anti-fingerprint layer, etc.

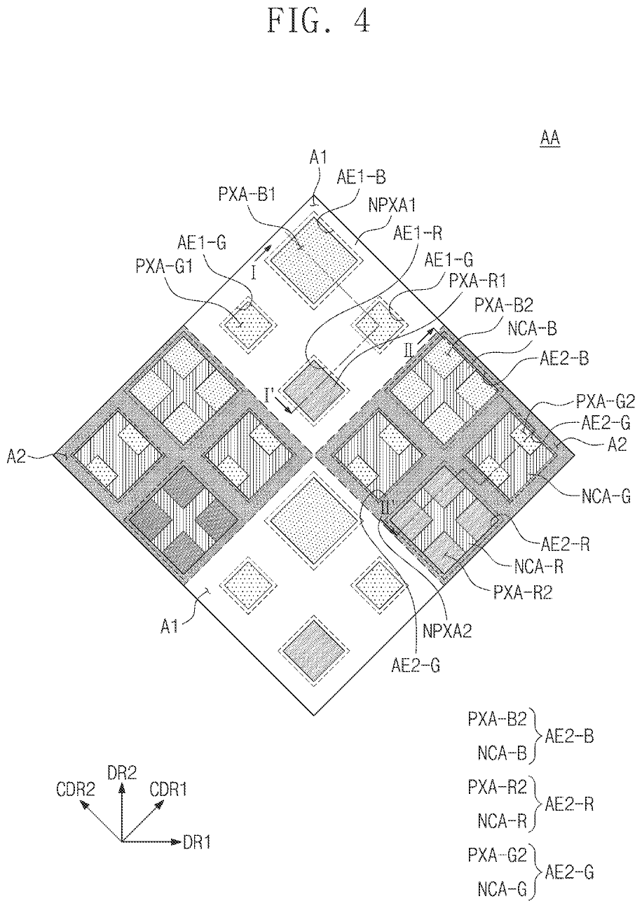

FIG. 4 is an enlarged plan view of a region AA of FIG. 2 according to an embodiment of the inventive concept.

FIG. 4 illustrates element regions included in different regions of the display panel 100 (see FIG. 3). The display panel 100 may include a first region A1 and a second region A2. The first region A1 and the second region A2 may be arranged to be spaced apart from each other in a first diagonal direction CDR1 and a second diagonal direction CDR2.

The first region A1 may include a plurality of (1-1)-th, (1-2)th, and (1-3)-th element regions AE1-B, AE1-G, and AE1-R and a first peripheral region NPXA1. The first peripheral region NPXA1 may surround the (1-1)-th, (1-2)th, and (1-3)-th element regions AE1-B, AE1-G, and AE1-R, sometimes referred to as the (1-1)-th to (1-3)-th element regions AE1-B, AE1-G, and AE1-R. The first peripheral region NPXA1 may overlap, on a plane, at least a portion of an edge of each of the (1-1)-th to (1-3)-th element regions AE1-B, AE1-G, and AE1-R.

In the inventive concept, the (1-1)-th to (1-3)-th element regions AE1-B, AE1-G, and AE1-R may each be defined as a region in which a ‘first electrode’, included in light-emitting elements that provide different color light, is disposed.

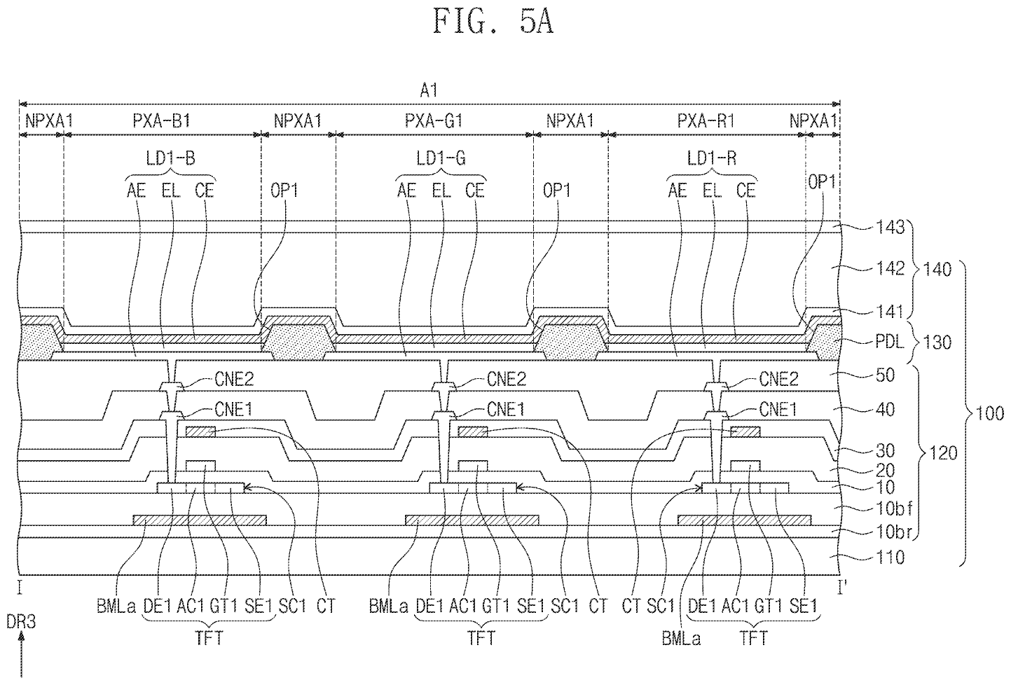

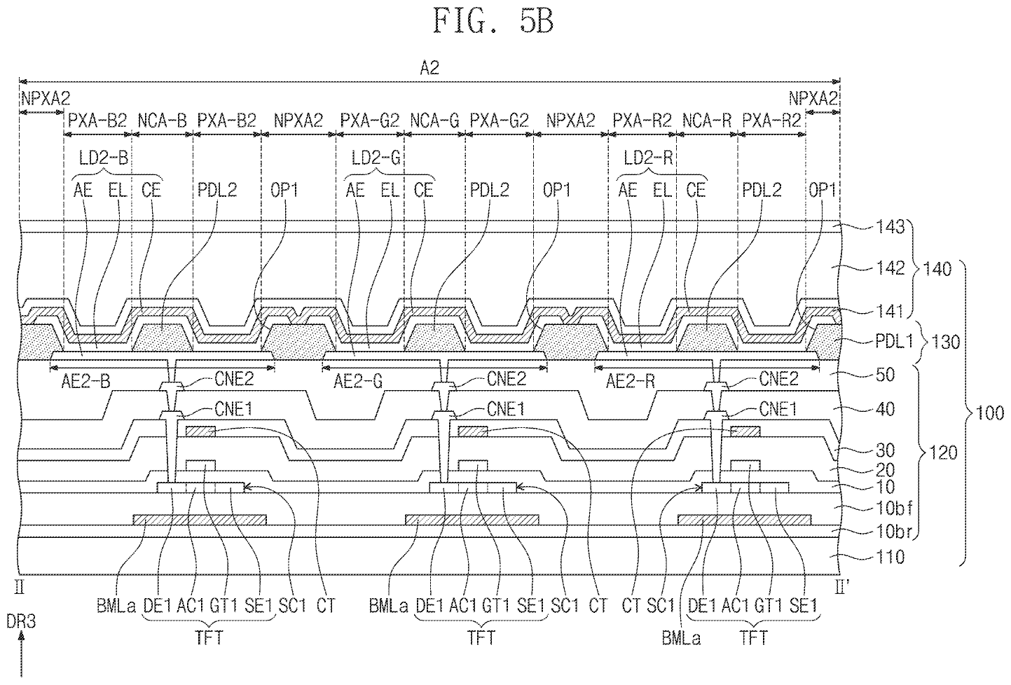

For example, as illustrated in FIG. 5A, the (1-1)-th element region AE1-B may be defined as a region in which a first electrode AE of a (1-1)-th light-emitting element LD1-B providing a first-color light is disposed.

The first region A1 of the display panel 100 may include a (1-1)-th light-emitting region PXA-B1 defined as a region in which light generated from the (1-1)-th light-emitting element LD1-B is substantially emitted.

The (1-2)-th element region AE1-G may be defined as a region in which a first electrode AE of a (1-2)-th light-emitting element LD1-G (see FIG. 5A) providing a second-color light is disposed.

According to this embodiment, two (1-2)-th element regions AE1-G may be provided in one first region A1. One of the (1-2)-th element regions AE1-G may be spaced apart from the (1-1)-th element region AE1-B in the first diagonal direction CDR1, and spaced apart from the (1-3)-th element region AE1-R in the second diagonal direction CDR2. The (1-2)-th element regions AE1-G may be spaced apart from each other in a first direction DR1. The other one of the (1-2)-th element regions AE1-G may be spaced apart from the (1-1)-th element region AE1-B in the second diagonal direction CDR2, and spaced apart from the (1-3)-th element region AE1-R in the first diagonal direction CDR1.

The first region A1 of the display panel 100 may include a (1-2)-th light-emitting region PXA-G1 defined as a region in which light generated from a (1-2)-th light-emitting element LD1-G (see FIG. 5A) is substantially emitted. A plurality of (1-2)-th light-emitting regions PXA-G1 may be included in one first region A1. The positions and number of the (1-2)-th light-emitting regions PXA-G1 may correspond to the positions and number of the (1-2)-th element regions AE1-G.

The (1-3)-th element region AE1-R may be defined as a region in which a first electrode AE of a (1-3)-th light-emitting element LD1-R (see FIG. 5A) providing a third-color light is disposed.

The first region A1 of the display panel 100 may include a (1-3)-th light-emitting region PXA-R1 defined as a region in which light generated from the (1-3)-th light-emitting element LD1-R (see FIG. 5A) is substantially emitted.

In this embodiment, the areas of the (1-1)-th light-emitting region PXA-B1, the (1-2)-th light-emitting region PXA-G1, and the (1-3)-th light-emitting region PXA-R1 of the first region A1 may be defined to respectively correspond to the areas of corresponding openings among first openings OP1 (see FIG. 5A) defined in a pixel-defining layer PDL (see FIG. 5A) disposed in the first region A1.

The second region A2 may include a plurality of (2-1)-th, (2-2)th, and (2-3)-th element regions AE2-B, AE2-G, and AE2-R and a second peripheral region NPXA2. The second peripheral region NPXA2 may surround the (2-1)-th, (2-2)th, and (2-3)-th element regions AE2-B, AE2-G, and AE2-R, sometimes called the (2-1)-th to (2-3)-th element regions AE2-B, AE2-G, and AE2-R.

The (2-1)-th element region AE2-B may include a plurality of (2-1)-th light-emitting regions PXA-B2 and a first non-light-emitting region NCA-B.

The (2-2)-th element region AE2-G may include a plurality of (2-2)-th light-emitting regions PXA-G2 and a second non-light-emitting region NCA-G.

The (2-3)-th element region AE2-R may include a plurality of (2-3)-th light-emitting regions PXA-R2 and a third non-light-emitting region NCA-R.

The first to third non-light-emitting regions NCA-B, NCA-G, and NCA-R included in the (2-1)-th to (2-3)-th element regions AE2-B, AE2-G, and AE2-R may each be defined as a region, among the (2-1)-th to (2-3)-th element regions AE2-B, AE2-G, and AE2-R, in which a portion of a first electrode AE (see FIG. 5B) is blocked by a second pixel-defining layer PDL2 (see FIG. 5B) to be described later.

In the inventive concept, the (2-1)-th to (2-3)-th element regions AE2-B, AE2-G, and AE2-R may each be defined as a region in which a ‘first electrode’, included in light-emitting elements that provide different color light, is disposed.

For example, as illustrated in FIG. 5B, the (2-1)-th element region AE2-B may be defined as a region in which a first electrode AE of a (2-1)-th light-emitting element LD2-B providing the first-color light is disposed.

The (2-1)-th element region AE2-B of the display panel 100 may include the (2-1)-th light-emitting regions PXA-B2 defined as regions in which light generated from the (2-1)-th light-emitting element LD2-B (see FIG. 5B) is substantially emitted.

According to this embodiment, the (2-1)-th element region AE2-B may be provided as four (2-1)-th light-emitting regions PXA-B2 spaced apart from each other in the first direction DR1 and the second direction DR2, or in the first diagonal direction CDR1 and the second diagonal direction CDR2, with the first non-light-emitting region NCA-B therebetween.

Likewise, the (2-2)-th element region AE2-G may be defined as a region in which a first electrode of a (2-2)-th light-emitting element LD2-G (see FIG. 5B) providing a second-color light is disposed.

According to this embodiment, two (2-2)-th element regions AE2-G may be provided in one second region A2. The (2-2)-th element regions AE2-G may be spaced apart from each other in the first direction DR1.

One of the (2-2)-th element regions AE2-G may be spaced apart from the (2-1)-th element region AE2-B in the first diagonal direction CDR1, and spaced apart from the (2-3)-th element region AE2-R in the second diagonal direction CDR2. The other one of the (2-2)-th element regions AE2-G may be spaced apart from the (2-1)-th element region AE2-B in the second diagonal direction CDR2, and spaced apart from the (2-3)-th element region AE2-R in the first diagonal direction CDR1.

The (2-2)-th element region AE2-G of the display panel 100 may include the (2-2)-th light-emitting regions PXA-G2 defined as regions in which light generated from the (2-2)-th light-emitting element LD2-G (see FIG. 5B) is substantially emitted.

The (2-2)-th light-emitting regions PXA-G2 may be divided into two groups. The (2-2)-th light-emitting regions PXA-G2 of a first group may overlap one of the (2-2)-th element regions AE2-G, and the (2-2)-th light-emitting regions PXA-G2 of a second group may overlap the other one of the (2-2)-th element regions AE2-G.

The first and second groups according to this embodiment may each include two (2-2)-th light-emitting regions PXA-G2.

The (2-2)-th light-emitting regions PXA-G2 of the first group may be spaced apart from the (2-1)-th light-emitting regions PXA-B2 in the first diagonal direction CDR1, and spaced apart from the (2-3)-th light-emitting regions PXA-R2 in the second diagonal direction CDR2.

The (2-2)-th light-emitting regions PXA-G2 of the second group may be spaced apart from the (2-2)-th light-emitting regions PXA-G2 of the first group in the first direction DR1, spaced apart from the (2-1)-th light-emitting regions PXA-B2 in the second diagonal direction CDR2, and spaced apart from the (2-3)-th light-emitting regions PXA-R2 in the first diagonal direction CDR1.

The (2-2)-th light-emitting regions PXA-G2 included in each of the first and second groups may be provided as two (2-2)-th light-emitting regions PXA-G2 spaced apart from each other in the first direction DR1 and the second direction DR2, or in the first diagonal direction CDR1 and the second diagonal direction CDR2, with the second non-light-emitting region NCA-G therebetween.

The (2-3)-th element region AE2-R may be defined as a region in which a first electrode AE of a (2-3)-th light-emitting element LD2-R (see FIG. 5B) providing a third-color light is disposed. The first- to third-color light may have different colors.

The (2-3)-th element region AE2-R of the display panel 100 may include the (2-3)-th light-emitting regions PXA-R2 defined as regions in which light generated from the (2-3)-th light-emitting element LD2-R (see FIG. 5B) is substantially emitted.

The (2-3)-th element region AE2-R may be provided as four (2-3)-th light-emitting regions PXA-R2 spaced apart from each other in the first direction DR1 and the second direction DR2, or in the first diagonal direction CDR1 and the second diagonal direction CDR2, with the third non-light-emitting region NCA-R therebetween.

The aforementioned first region A1 and second region A2 may be provided in plurality in the display region 1000A (see FIG. 1). The first regions A1 and the second regions A2 may be arranged with a distance along the first diagonal direction CDR1 and the second diagonal direction CDR2.

FIG. 5A is a cross-sectional view taken along line I-I′ of FIG. 4 according to an embodiment of the inventive concept.

Referring to FIG. 5A, a cross-sectional view of a region, of the first region A1, overlapping the (1-1)-th element region AE1-B, the (1-2)-th element region AE1-G, and the (1-3)-th element region AE1-R is exemplarily illustrated. The light-emitting elements LD1-B, LD1-G, and LD1-R emitting different color light and a transistor TFT connected thereto are illustrated. The transistor TFT may be one of a plurality of transistors included in a driving circuit of the pixels PX (see FIG. 2). In this embodiment, the transistor TFT is described as a silicon transistor, but the transistor TFT may be a metal-oxide transistor.

A base substrate 110 may correspond to the base substrate 110 described with reference to FIG. 3. A barrier layer 10br may be disposed on the base substrate 110. The barrier layer 10br may prevent foreign substances from being introduced from the outside. The barrier layer 10br may include at least one inorganic layer. The barrier layer 10br may include a silicon oxide layer and a silicon nitride layer. Such layers may each be provided in plurality, and the silicon oxide layers and the silicon nitride layers may be alternately stacked.

A shielding electrode BMLa may be disposed on the barrier layer 10br. The shielding electrode BMLa may include metal. The shielding electrode BMLa may include molybdenum (Mo) having good heat resistance, molybdenum (Mo)-containing alloy, titanium (Ti), or titanium (Ti)-containing alloy. The shielding electrode BMLa may receive a bias voltage.

The shielding electrode BMLa may prevent electrical potential due to polarization from affecting the silicon transistor TFT. The shielding electrode BMLa may prevent external light from reaching the silicon transistor TFT. According to an embodiment of the inventive concept, the shielding electrode BMLa may be a floating electrode in a form of being isolated from another electrode or wiring.

A buffer layer 10bf may be disposed on the barrier layer 10br. The buffer layer 10bf may prevent diffusion of metal atoms or impurities from the base substrate 110 to a semiconductor pattern SC1 thereabove. The buffer layer 10bf may include at least one inorganic layer. The buffer layer 10bf may include a silicon oxide layer and a silicon nitride layer.

The semiconductor pattern SC1 may be disposed on the buffer layer 10bf. The semiconductor pattern SC1 may include a silicon semiconductor. For example, the silicon semiconductor may include amorphous silicon, polycrystalline silicon, and the like. For example, the semiconductor pattern SC1 may include a low temperature polysilicon.

The semiconductor pattern SC1 may include a first region with high conductivity and a second region with low conductivity. The first region may be doped with an N-type dopant or a P-type dopant. A P-type transistor may include a doped region which is doped with a P-type dopant, and an N-type transistor may include a doped region which is doped with an N-type dopant. The second region may be an undoped region, or a doped region which is doped with lower concentrations than the first region.

The conductivity of the first region may be greater than the conductivity of the second region, and the first region may substantially serve as an electrode or a signal line. The second region may substantially correspond to an active region (or channel) of the transistor. In other words, a portion of the semiconductor pattern may be an active region of the transistor, another portion may be a source or a drain of the transistor, and still another portion may be a connection electrode or a connection signal line.

A source region SE1 (or source), an active region AC1 (or channel), and a drain region DE1 (or drain) of the transistor TFT may be formed from the semiconductor pattern SC1. The source region SE1 and the drain region DE1 may extend from the active region AC1 in the opposite directions to each other on a cross-section.

A first insulation layer 10 may be disposed on the buffer layer 10bf. The first insulation layer 10 may overlap the plurality of pixels PX (see FIG. 2) in common, and cover the semiconductor pattern SC1. The first insulation layer 10 may include an inorganic layer and/or organic layer, and have a single-layer or multi-layer structure.

The inorganic layer may include at least one of aluminum oxide, titanium oxide, silicon oxide, silicon nitride, silicon oxynitride, zirconium oxide, or hafnium oxide, but an embodiment of the inventive concept is not limited thereto.

In this embodiment, the first insulation layer 10 may be a silicon oxide layer as a single layer. An insulation layer of a circuit layer 120 to be described later, as well as the first insulation layer 10, may be an inorganic layer and/or organic layer, and may have a single-layer or multi-layer structure. The inorganic layer may include at least one of the aforementioned materials, but an embodiment of the inventive concept is not limited thereto.

A gate GT1 of the transistor TFT is disposed on the first insulation layer 10. The gate GT1 may be a portion of a metal pattern. The gate GT1 overlaps the active region AC1. In a doping process of the semiconductor pattern, the gate GT1 may function as a mask. The gate GT1 may include titanium (Ti), silver (Ag), silver (Ag)-containing alloy, molybdenum (Mo), molybdenum (Mo)-containing alloy, aluminum (Al), aluminum (Al)-containing alloy, aluminum nitride (AlN), tungsten (W), tungsten nitride (WN), copper (Cu), indium tin oxide (ITO), indium zinc oxide (IZO), and the like, but an embodiment of the inventive concept is not limited particularly thereto.

A second insulation layer 20 may be disposed on the first insulation layer 10, and cover the gate GT1. A third insulation layer 30 may be disposed on the second insulation layer 20. A storage electrode CT may be disposed between the second insulation layer 20 and the third insulation layer 30. The storage electrode CT may overlap the gate GT1. The gate GT1 and the storage electrode CT may form a capacitor included in a driving circuit of the pixel PX (see FIG. 2).

A first connection electrode CNE1 may be disposed on the third insulation layer 30. The first connection electrode CNE1 may be connected to the drain region DE1 of the transistor TFT through a contact hole passing through the first to third insulation layers 10, 20, and 30.

A fourth insulation layer 40 may be disposed on the third insulation layer 30. A second connection electrode CNE2 may be disposed on the fourth insulation layer 40. The second connection electrode CNE2 may be connected to the first connection electrode CNE1 through a contact hole passing through the fourth insulation layer 40. A fifth insulation layer 50 may be disposed on the fourth insulation layer 40, and cover the second connection electrode CNE2. The stacked structure of the first to fifth insulation layers 10 to 50 is only an example, and in addition to the first to fifth insulation layers 10 to 50, a conductive layer and an insulation layer may be further disposed.

The fourth insulation layer 40 and the fifth insulation layer 50 may each be an organic layer. For example, the organic layer may include a general-purpose polymer such as benzo-cyclobutene (BCB), polyimide, hexa-methyl-di-siloxane (HMDSO), polymethylmethacrylate (PMMA), or polystyrene (PS), a polymer derivative having a phenol-based group, an acrylate-based polymer, an imide-based polymer, an aryl ether-based polymer, an amide-based polymer, a fluorine-based polymer, a p-xylene-based polymer, a vinyl alcohol-based polymer, and a blend thereof.

The light-emitting elements LD1-B, LD1-G, and LD1-R may each include a first electrode AE (or pixel electrode), a light-emitting layer EL, and a second electrode CE (or common electrode). The first electrode AE may be disposed on the fifth insulation layer 50. The first electrode AE may be a (semi-)transmissive electrode or a reflective electrode. The first electrode AE may include a reflective layer formed of Ag, Mg, Al, Pt, Pd, Au, Ni, Nd, Ir, Cr, or a compound thereof, etc., and a transparent or semi-transparent electrode layer formed on the reflective layer. The transparent or semi-transparent electrode layer may include at least one selected from the group consisting of indium tin oxide (ITO), indium zinc oxide (IZO), indium gallium zinc oxide (IGZO), zinc oxide (ZnO) or indium oxide (In₂O₃), and aluminum-doped zinc oxide (AZO). For example, the first electrode AE may include a stacked structure of ITO/Ag/ITO.

According to the inventive concept, the first region A1 may include a pixel-defining layer PDL. The pixel-defining layer PDL may be disposed on the fifth insulation layer 50. In the pixel-defining layer PDL, a first opening OP1, which extends to and exposes at least a portion of the first electrode AE of the light-emitting element LD1-B, may be defined. The pixel-defining layer PDL of the first region A1 may cover a portion of the first electrode AE.

As described above, the (1-1)-th light-emitting region PXA-B1 of the first region A1, in which light generated from the (1-1)-th light-emitting element LD1-B is substantially provided, may be determined according to the area of the first opening OP1 defined in the pixel-defining layer PDL of the first region A1. The first peripheral region NPXA1 adjacent to the (1-1)-th light-emitting region PXA-B1 may be defined as a region overlapping the pixel-defining layer PDL of the first region A1.

The (1-2)-th light-emitting region PXA-G1 of the first region A1, in which light generated from the (1-2)-th light-emitting element LD1-G is substantially provided, may be determined according to the area of the first opening OP1 defined in the pixel-defining layer PDL of the first region A1.

The (1-3)-th light-emitting region PXA-R1 of the first region A1, in which light generated from the (1-3)-th light-emitting element LD1-R is substantially provided, may be determined according to the area of the first opening OP1 defined in the pixel-defining layer PDL of the first region A1.

Although not illustrated in the drawing, a hole control layer may be disposed between the first electrode AE and the light-emitting layer EL. The hole control layer may include a hole transport layer, and may further include a hole injection layer. An electron control layer may be disposed between the light-emitting layer EL and the second electrode CE. The electron control layer may include an electron transport layer, and may further include an electron injection layer.

An encapsulation layer 140 may be disposed on the light-emitting elements LD1-B, LD-G, and LD-R of the first region A1. The encapsulation layer 140 may include a first inorganic encapsulation layer 141, an organic encapsulation layer 142, and a second inorganic encapsulation layer 143 that are stacked in sequence, but the layers constituting the encapsulation layer 140 are not limited thereto.

The first and second inorganic encapsulation layers 141 and 143 may protect a light-emitting element layer 130 from moisture and oxygen, and the organic encapsulation layer 142 may protect the light-emitting element layer 130 from foreign substances such as dust particles. The first and second inorganic encapsulation layers 141 and 143 may include inorganic materials. The first and second inorganic encapsulation layers 141 and 143 may include a silicon nitride layer, a silicon oxynitride layer, a silicon oxide layer, a titanium oxide layer, an aluminum oxide layer, or the like. The organic encapsulation layer 142 may include an organic material. The organic encapsulation layer 142 may include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyimide-based resin, a polyamide-based resin, or a perylene-based resin.

FIG. 5B is a cross-sectional view taken along line II-II′ of FIG. 4 according to an embodiment of the inventive concept.

Referring to FIG. 5B, a cross-sectional view of a region, of the second region A2, overlapping the (2-1)-th element region AE2-B, the (2-2)-th element region AE2-G, and the (2-3)-th element region AE2-R is exemplarily illustrated. The light-emitting elements LD2-B, LD2-G, and LD2-R respectively emitting light of different colors and transistors TFT connected thereto are illustrated. The transistor TFT may be one of a plurality of transistors included in a driving circuit of the pixels PX (see FIG. 2). Hereinafter, descriptions of the same components as those described with reference to FIG. 5A are omitted.

The (2-1)-th to (2-3)-th light-emitting elements LD2-B, LD2-G, and LD2-R disposed in the second region A2 may each include a first electrode AE, a light-emitting layer EL, and a second electrode CE. The (2-1)-th to (2-3)-th light-emitting elements LD2-B, LD2-G, and LD2-R disposed in the second region A2 may each include a plurality of sub-pixels.

The second region A2 may include a first pixel-defining layer PDL1. The first pixel-defining layer PDL1 may be disposed on the fifth insulation layer 50. In the first pixel-defining layer PDL1, a first opening OP1, which extends to and exposes at least a portion of the first electrode AE of each of the (2-1)-th to (2-3)-th light-emitting elements LD2-B, LD2-G, and LD2-R, may be defined. The first pixel-defining layer PDL1 may cover a portion of the first electrode AE.

The second region A2 may include a second pixel-defining layer PDL2. The second pixel-defining layer PDL2 may be disposed on the first electrode AE exposed by the first opening OP1 of the first pixel-defining layer PDL1. The second pixel-defining layer PDL2 may overlap the first to third non-light-emitting regions NCA-B, NCA-G, and NCA-R. That is, the second pixel-defining layer PDL2 may be disposed on the first electrode AE, and may thus define the first to third non-light-emitting regions NCA-B, NCA-G, and NCA-R. Accordingly, the (2-1)-th to (2-3)-th light-emitting regions PXA-B2, PXA-G2, and PXA-R2 may each be disposed in plurality on one first electrode AE disposed in the second region A2.

Each of the (2-1)-th light-emitting regions PXA-B2 may be adjacent to the second peripheral region NPXA2 and the first non-light-emitting region NCA-B. Each of the (2-2)-th light-emitting regions PXA-G2 may be adjacent to the second peripheral region NPXA2 and the second non-light-emitting region NCA-G. Each of the (2-3)-th light-emitting regions PXA-R2 may be adjacent to the second peripheral region NPXA2 and the third non-light-emitting region NCA-R.

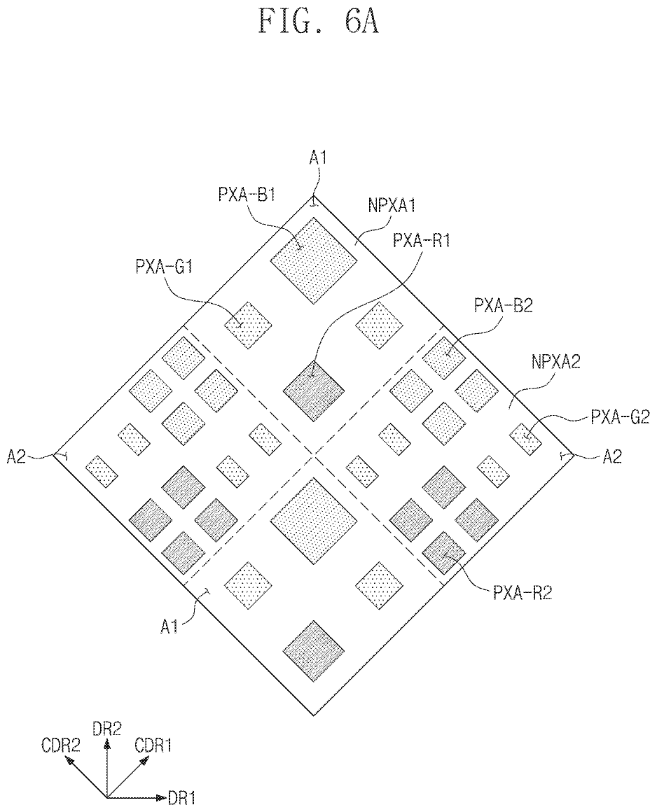

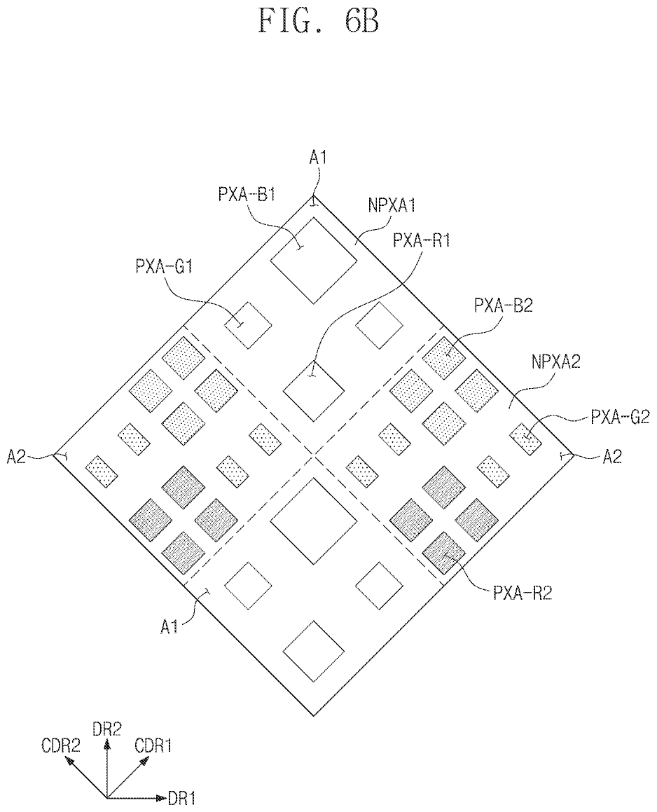

FIG. 6A is an enlarged plan view of the region AA of FIG. 2 in a first operation mode according to an embodiment of the inventive concept. FIG. 6B is an enlarged plan view of the region AA of FIG. 2 in a second operation mode according to an embodiment of the inventive concept.

Referring to FIG. 6A, the display device DD (see FIG. 3) according to the inventive concept may operate in two modes. The ‘first operation mode’ may be a state in which (1-1)-th to (1-3)-th element regions AE1-B, AE1-G, and AE1-R included in first regions A1 and (2-1)-th to (2-3)-th element regions AE2-B, AE2-G, and AE2-R included in second regions A2 of the display panel 100 (see FIG. 3) are activated to provide light to corresponding light-emitting regions.

Referring to FIG. 6B, the ‘second operation mode’ may be defined as a state in which the (1-1)-th to (1-3)-th element regions AE1-B, AE1-G, and AE1-R included in the first region A1 are deactivated, and only the (2-1)-th to (2-3)-th element regions AE2-B, AE2-G, and AE2-R included in the second region A2 are activated to provide light to the corresponding light-emitting regions.

Therefore, the area of the activated light-emitting regions may become relatively smaller in the second operation mode than in the first operation mode, and thus a low-pixel image may be provided to a user.

In general, the first operation mode may correspond to a mode in which the display device DD (see FIG. 3) is operated. The second operation mode may be carried out when the display device DD (see FIG. 3) is used for a particular purpose. For example, in the second operation mode which is a private mode, it may be possible to make the display region 1000A (see FIG. 1) being viewed only to a user, but not to people around the user, thereby preventing personal information from being disclosed.

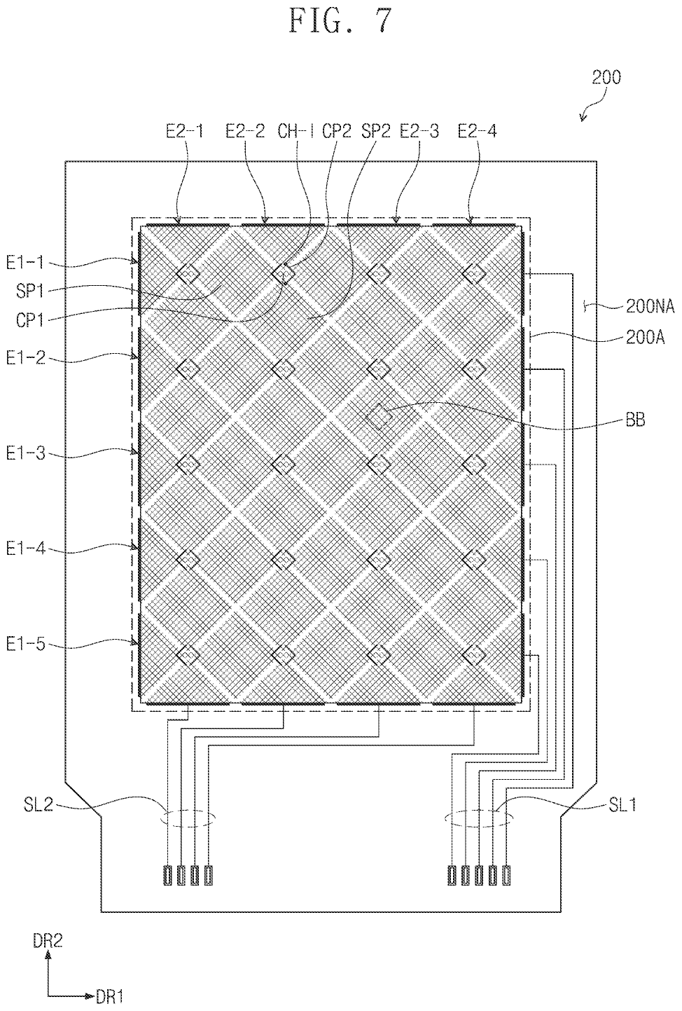

FIG. 7 is a plan view of an input sensor 200 according to an embodiment of the inventive concept.

Referring to FIG. 7, the input sensor 200 includes a detecting region 200A and a non-detecting region 200NA adjacent to the detecting region 200A. The detecting region 200A and the non-detecting region 200NA respectively correspond to the display region 1000A and the non-display region 1000N illustrated in FIG. 1.

The input sensor 200 includes first sensing electrodes E1-1 to E1-5 and second sensing electrodes E2-1 to E2-4 which are disposed in the detecting region 200A and insulated from each other while crossing each other. Variance in mutual capacitance formed between the first sensing electrodes E1-1 to E1-5 and the second sensing electrodes E2-1 to E2-4 may be calculated to detect an external input.

The input sensor 200 includes first signal lines SL1 disposed in the non-detecting region 200NA and electrically connected to the first sensing electrodes E1-1 to E1-5, and second signal lines SL2 disposed in the non-detecting region 200NA and electrically connected to the second sensing electrodes E2-1 to E2-4.

The first sensing electrodes E1-1 to E1-5 and the second sensing electrodes E2-1 to E2-4 may each include a plurality of conductive lines crossing each other. The first sensing electrodes E1-1 to E1-5 and the second sensing electrodes E2-1 to E2-4 may each have mesh lines. A plurality of openings overlapping the light-emitting regions included in the aforementioned first region A1 and the second region A2 may be defined in the mesh lines.

Either of the first sensing electrodes E1-1 to E1-5 or the second sensing electrodes E2-1 to E2-4 may have an integrated shape. In this embodiment, it is exemplarily illustrated that the first sensing electrodes E1-1 to E1-5 have the integrated shape. The first sensing electrodes E1-1 to E1-5 may include sensing parts SP1 and middle parts CP1.

The second sensing electrodes E2-1 to E2-4 may each include sensing patterns SP2 and bridge patterns CP2 (or connection patterns). Two sensing patterns SP2 adjacent to each other may be connected to two bridge patterns CP2 through a contact hole CH-I, but the number of the bridge patterns is not limited thereto.

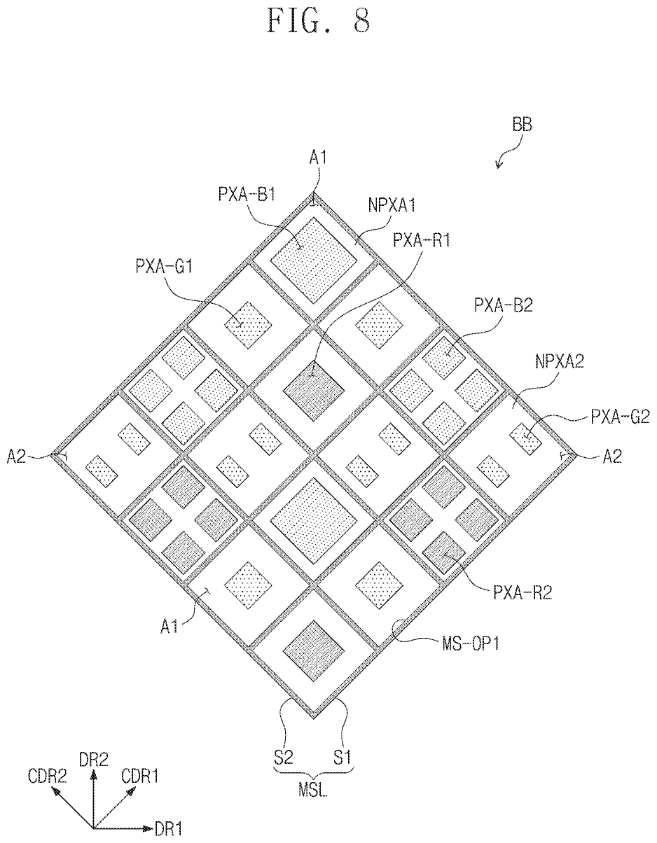

FIG. 8 is an enlarged plan view of a region BB of FIG. 7 according to an embodiment of the inventive concept.

Referring to FIG. 8, the sensing patterns SP2 of the first sensing electrodes E1-1 to E1-5 (see FIG. 5) and the second sensing electrodes E2-1 to E2-4 (see FIG. 7) may include mesh lines MSL extending in a first diagonal direction CDR1 and a second diagonal direction CDR2.

The mesh line MSL may include a first line S1 and a second line S2. The first line S1 may extend in the first diagonal direction CDR1, and the second line S2 may extend in the second diagonal direction CDR2. The first line S1 and the second line S2 are integrally provided to form a mutually extended pattern, but the first line S1 and the second line S2 are separately described for the convenience of description.

In the mesh line MSL, mesh openings MS-OP1 may be defined as the first line S1 and the second line S2 are arranged crosswise. In this embodiment, the mesh openings MS-OP1 may have the same shape.

In this embodiment, (1-1)-th to (1-3)-th light-emitting regions PXA-B1, PXA-G1, and PXA-R1 of the first region A1 may respectively be surrounded by the corresponding openings among the mesh openings MS-OP1. Accordingly, the mesh openings MS-OP1 overlapping the first region A1 may each surround one of the light-emitting regions.

In each of (2-1)-th to (2-3)-th light-emitting regions PXA-B2, PXA-G2, and PXA-R2 of the second region A2, light-emitting regions that provide the same color may be grouped and surrounded by one mesh opening MS-OP1. That is, four (2-1)-th light-emitting regions PXA-B2 may be surrounded by one mesh opening MS-OP1, two (2-2)-th light-emitting regions PXA-G2 of a first group may be surrounded by another mesh opening MS-OP1, and two (2-2)-th light-emitting regions PXA-G2 of a second group may be surrounded by another mesh opening MS-OP1, and four (2-3)-th light-emitting regions PXA-R2 may be surrounded by the remaining one mesh opening MS-OP1.

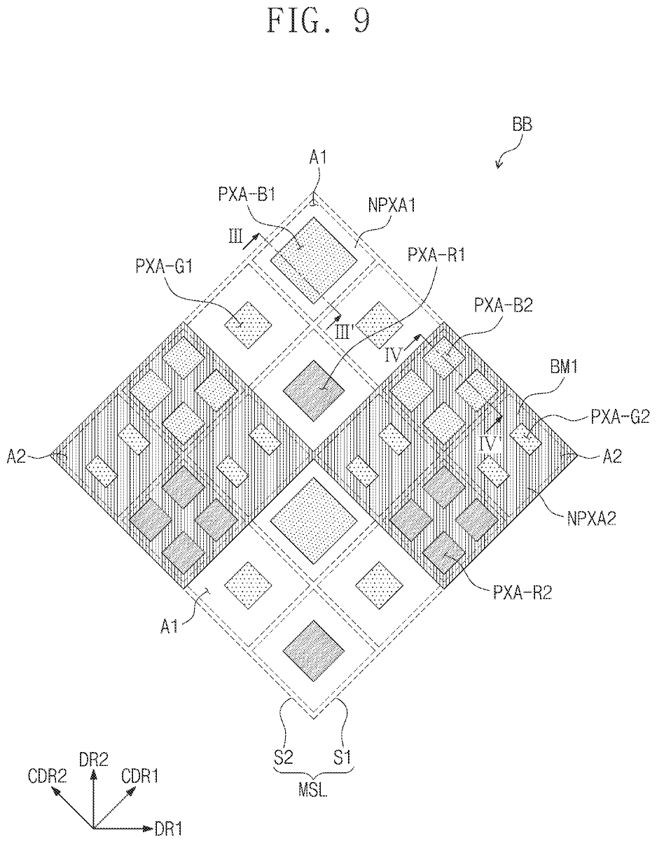

FIG. 9 is an enlarged plan view of the region BB of FIG. 7 according to an embodiment of the inventive concept.

In particular, FIG. 9 illustrates the arrangement relationship between a first light-blocking pattern BM1 disposed in the light control layer 300 (see FIG. 3) and light-emitting regions disposed in a first region A1 and a second region A2. A mesh line MSL is illustrated in dotted line.

The first light-blocking pattern BM1 may be disposed only in the second region A2 and may not overlap the first region A1. The first light-blocking pattern BM1 may not overlap (2-1)-th to (2-3)-th light-emitting regions PXA-B2, PXA-G2, and PXA-R2 disposed in the second region A2. That is, the first light-blocking pattern BM1 may overlap the second peripheral region NPXA2 (see FIG. 4), which is a non-light-emitting region of the second region A2, and overlap the first to third non-light-emitting regions NCA-B, NCA-G, and NCA-R (see FIG. 4).

The first light-blocking pattern BM1 may be disposed surrounding the (2-1)-th light-emitting regions PXA-B2, the (2-2)-th light-emitting regions PXA-G2, and the (2-3)-th light-emitting regions PXA-R2. The material of the first light-blocking pattern BM1 is not limited to any one material as long as the material absorbs light.

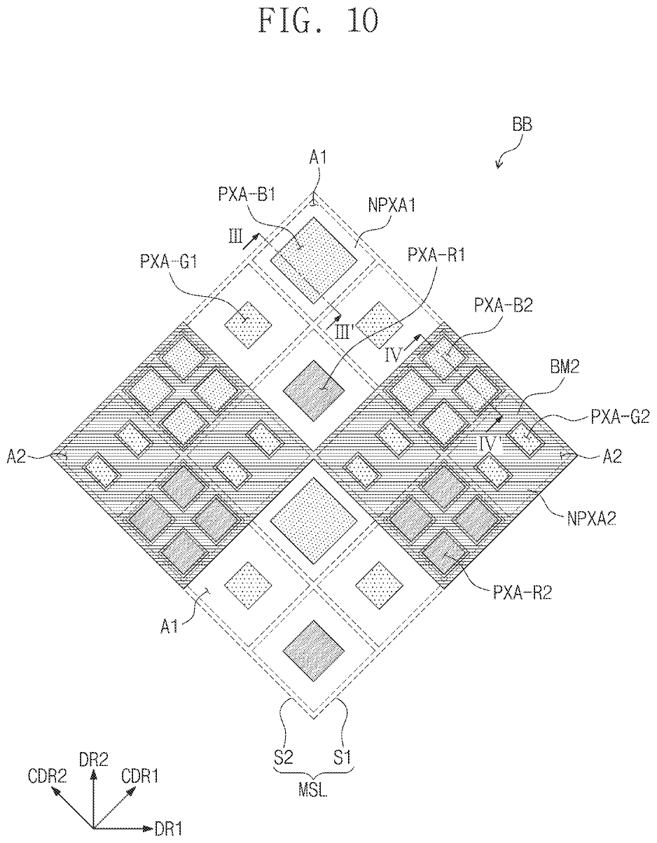

FIG. 10 is an enlarged plan view of the region BB of FIG. 7 according to an embodiment of the inventive concept.

In particular, FIG. 10 illustrates the arrangement relationship between a second light-blocking pattern BM2 disposed in the light control layer 300 (see FIG. 3) and light-emitting regions disposed in a first region A1 and a second region A2.

The second light-blocking pattern BM2 may be disposed only in the second region A2, and may not overlap the first region A1. The second light-blocking pattern BM2 may overlap a first light-blocking pattern BM1 (see FIG. 9). The second light-blocking pattern BM2 may not overlap (2-1)-th to (2-3)-th light-emitting regions PXA-B2, PXA-G2, and PXA-R2 disposed in the second region A2. That is, the second light-blocking pattern BM2 may overlap the second peripheral region NPXA2 (see FIG. 4), which is a non-light-emitting region of the second region A2, and overlap the first to third non-light-emitting regions NCA-B, NCA-G, and NCA-R (see FIG. 4).

The second light-blocking pattern BM2 may be disposed surrounding the (2-1)-th light-emitting regions PXA-B2, the (2-2)-th light-emitting regions PXA-G2, and the (2-3)-th light-emitting regions PXA-R2. The material of the second light-blocking pattern BM2 is not limited to any one material as long as the material absorbs light.

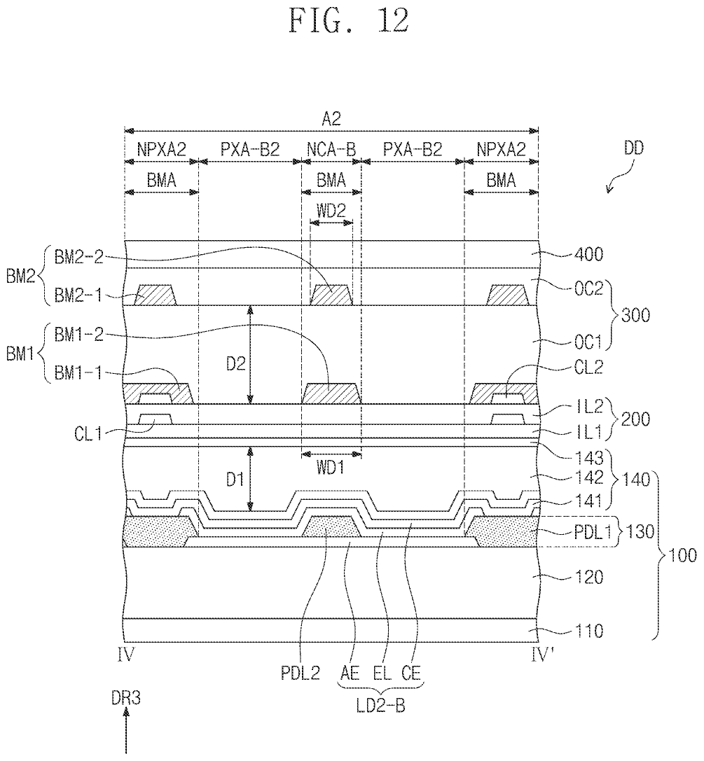

The line width of the second light-blocking pattern BM2 may be smaller than that of the first light-blocking pattern BM1 (see FIG. 9). Accordingly, the second light-blocking pattern BM2 may be spaced farther apart from each of the (2-1)-th to (2-3)-th light-emitting regions PXA-B2, PXA-G2, and PXA-R2 than the first light-blocking pattern BM1 (see FIG. 9). This will be described later with reference to FIG. 12.

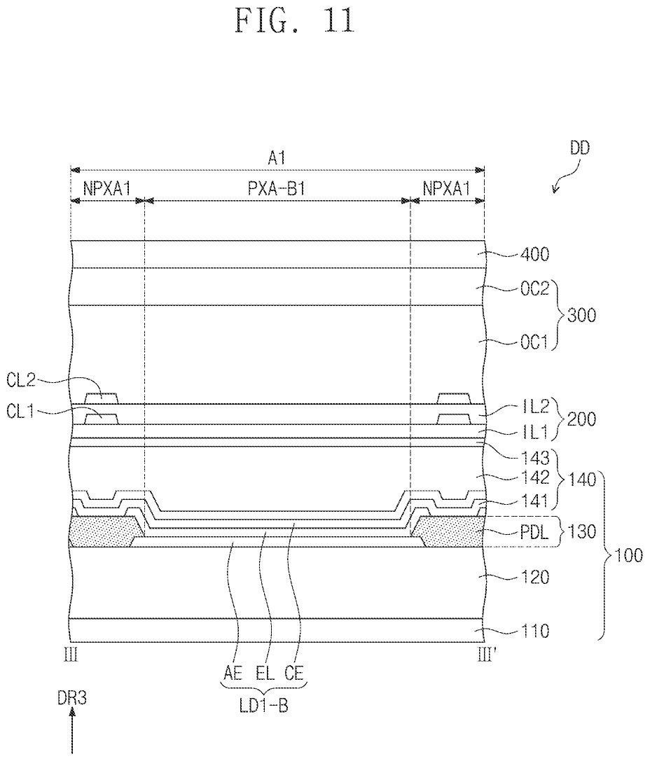

FIG. 11 is a cross-sectional view taken along line III-III′ of FIG. 9 according to an embodiment of the inventive concept. In particular, FIG. 11 is a cross-sectional view taken along line III-III′ of FIGS. 9 and 10 in a state where a display panel 100, an input sensor 200, a light control layer 300, and an anti-reflection layer 400 are stacked. The display panel 100, the input sensor 200, the light control layer 300, and the anti-reflection layer 400 illustrated in FIG. 11 may respectively correspond to the display panel 100, the input sensor 200, the light control layer 300, and the anti-reflection layer 400 described with reference to FIG. 3.

FIG. 11 exemplarily illustrates a cross-sectional view of a region, of the first region A1, overlapping the (1-1)-th light-emitting region PXA-B1. Accordingly, the cross-sectional view to be described below may be applied in common for a (1-2)-th light-emitting region PXA-G1 and a (1-3)-th light-emitting region PXA-R1.

The input sensor 200 may include a first sensing insulation layer IL1 and a second sensing insulation layer IL2. The first sensing insulation layer IL1 may be disposed on an encapsulation layer 140. A first input-sensing electrode CL1 may be disposed on the first sensing insulation layer IL1. The second sensing insulation layer IL2 may be disposed on the first sensing insulation layer IL1. A second input-sensing electrode CL2 may be disposed on the second sensing insulation layer IL2. The first sensing insulation layer IL1 and the second sensing insulation layer IL2 may include inorganic materials.

The first input-sensing electrode CL1 and the second input-sensing electrode CL2 may each correspond to either of first sensing electrodes E1-1 to E1-5 or second sensing electrodes E2-1 to E2-4 (see FIG. 7). The first input-sensing electrode CL1 and the second input-sensing electrode CL2 may each overlap the first peripheral region NPXA1 that is a non-light-emitting region of the first region A1.

The light control layer 300 may include a first cover layer OC1 and a second cover layer OC2. The first cover layer OC1 may be disposed on the second sensing insulation layer IL2 of the input sensor 200. The second cover layer OC2 may be disposed on the first cover layer OC1. The first cover layer OC1 and the second cover layer OC2 may each include an organic material. For example, at least one of the first cover layer OC1 or the second cover layer OC2 may include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyimide-based resin, a polyamide-based resin, or a perylene-based resin.

A first light-blocking pattern BM1 (see FIG. 12) and a second light-blocking pattern BM2 (see FIG. 12) may not overlap the first region A1. Accordingly, light emitted from the (1-1)-th to (1-3)-th light-emitting elements LD1-B, LD1-G, and LD1-R (see FIGS. 5A and 10) of the first region A1 may not be blocked by the first and second light-blocking patterns BM1 and BM2 (see FIG. 12), and may thus be viewed at a larger viewing angle.

The anti-reflection layer 400 may be disposed on the light control layer 300. The anti-reflection layer 400 may be bonded to the light control layer 300 by an adhesive layer. The anti-reflection layer 400 may reduce the reflectance for external light.

FIG. 12 is a cross-sectional view taken along line IV-IV′ of FIGS. 9 and 10 according to an embodiment of the inventive concept. In particular, FIG. 12 is a cross-sectional view taken along line IV-IV′ of FIGS. 9 and 10 in a state where a display panel 100, an input sensor 200, a light control layer 300, and an anti-reflection layer 400 are stacked. The display panel 100, the input sensor 200, the light control layer 300, and the anti-reflection layer 400 illustrated in FIG. 12 may respectively correspond to the display panel 100, the input sensor 200, the light control layer 300, and the anti-reflection layer 400 described with reference to FIG. 3.

FIG. 12 exemplarily illustrates a cross-sectional view of a region, of the second region A2, overlapping the (2-1)-th light-emitting region PXA-B2. Accordingly, the cross-sectional view to be described below may be applied in common for a (2-2)-th light-emitting region PXA-G2 and a (2-3)-th light-emitting region PXA-R2 of the second region A2.

Referring to FIG. 12, the light control layer 300 may include a first cover layer OC1, a second cover layer OC2, a first light-blocking pattern BM1, and a second light-blocking pattern BM2. The first light-blocking pattern BM1 and the second light-blocking pattern BM2 may not be disposed in the first region A1 (see FIG. 10), and may be disposed only in the second region A2. The first light-blocking pattern BM1 may be disposed on a second sensing insulation layer IL2, and covered by the first cover layer OC1. The second light-blocking pattern BM2 may be disposed on the first cover layer OC1, and covered by the second cover layer OC2.

A first input-sensing electrode CL1 and a second input-sensing electrode CL2 may each overlap the second peripheral region NPXA2 that is a non-light-emitting region of the second region A2.

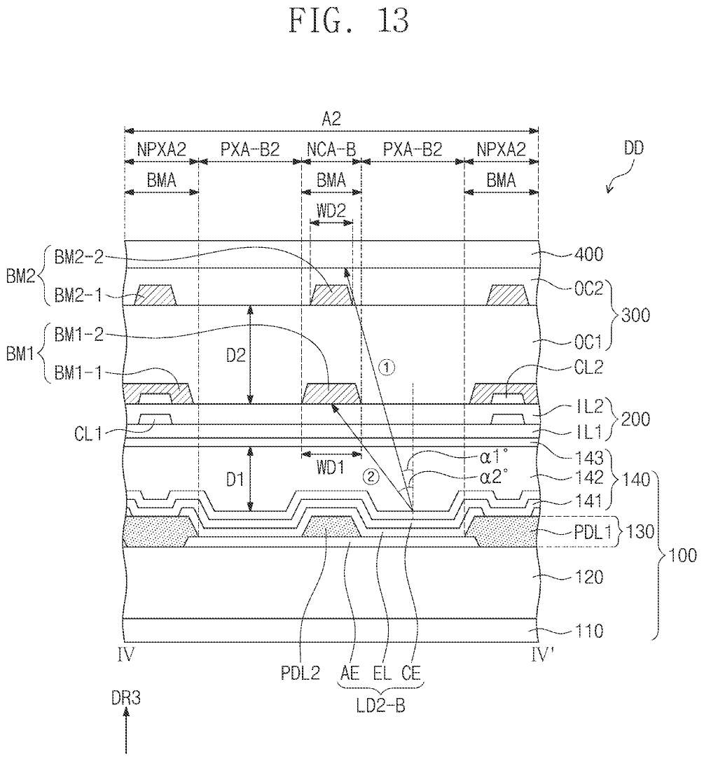

The first light-blocking pattern BM1 may be disposed on a same layer as the second input-sensing electrode CL2. The first light-blocking pattern BM1 may cover a portion of the second input-sensing electrode CL2 overlapping the second region A2. There may be no additional cover layer present between the second input-sensing electrode CL2 and the first light-blocking pattern BM1, and thus the first light-blocking pattern BM1 may be disposed adjacent to the (2-1)-th light-emitting element LD2-B in the second region A2. Accordingly, the first light-blocking pattern BM1 may prevent leakage of light at a large viewing angle. This will be described later with reference to FIG. 13.

The first light-blocking pattern BM1 may include a (1-1)-th light-blocking pattern BM1-1 and a (1-2)-th light-blocking pattern BM1-2. The (1-1)-th light-blocking pattern BM1-1 may overlap a first pixel-defining layer PDL1. The (1-1)-th light-blocking pattern BM1-1 may overlap the second peripheral region NPXA2. A light-blocking region BMA may be a region corresponding to the first light-blocking pattern BM1.

The (1-2)-th light-blocking pattern BM1-2 may overlap a second pixel-defining layer PDL2 disposed on the first electrode AE. The (1-2)-th light-blocking pattern BM1-2 may overlap the first non-light-emitting region NCA-B. In this embodiment, the (1-1)-th light-blocking pattern BM1-1 and the (1-2)-th light-blocking pattern BM1-2 may include a same material, and have a mutually-connected integral pattern.

The second light-blocking pattern BM2 may include a (2-1)-th light-blocking pattern BM2-1 and a (2-2)-th light-blocking pattern BM2-2. The second light-blocking pattern BM2 may be disposed farther away from the display panel 100 than the first light-blocking pattern BM1. The (2-1)-th light-blocking pattern BM2-1 may overlap the (1-1)-th light-blocking pattern BM1-1. The (2-1)-th light-blocking pattern BM2-1 may overlap the second peripheral region NPXA2.

The (2-2)-th light-blocking pattern BM2-2 may overlap the second pixel-defining layer PDL2 disposed on the first electrode AE. The (2-2)-th light-blocking pattern BM2-2 may overlap the first non-light-emitting region NCA-B. In this embodiment, the (2-1)-th light-blocking pattern BM2-1 and the (2-2)-th light-blocking pattern BM2-2 may include a same material, and have a mutually-connected integral pattern.

According to the inventive concept, when the display device DD (see FIG. 2) operates in a second operation mode, light emitted from the (2-1)-th light-emitting element LD2-B disposed in the second region A2 may be blocked by the first light-blocking pattern BM1 and the second light-blocking pattern BM2 at a predetermined angle. That is, as the viewing angle, at which the display device DD (see FIG. 2) is viewed from the side, is greater, the light-blocking area becomes larger.

Therefore, in the second operation mode, a user of the display device DD (see FIG. 2) may view the display region 1000A (see FIG. 1), but people close to the user may not view the display region 1000A (see FIG. 1). Accordingly, it may be possible to provide the display device DD (see FIG. 2) with an improved private mode function.

According to this embodiment, the (1-2)-th light-blocking pattern BM1-2 may have a first line width WD1. The (2-2)-th light-blocking pattern BM2-2 may have a second line width WD2. The first line width WD1 may be greater than the second line width WD2. Accordingly, the (1-2)-th light-blocking pattern BM1-2 adjacent to the (2-1)-th light-emitting element LD2-B may effectively prevent leakage of light at a large viewing angle. This will be described later with reference to FIG. 13.

However, an embodiment of the inventive concept is not limited to only the case where the first line width WD1 of the (1-2)-th light-blocking pattern BM1-2 is greater than the second line width WD2 of the (2-2)-th light-blocking pattern BM2-2. For example, the first line width WD1 of the (1-2)-th light-blocking pattern BM1-2 may be same as the second line width WD2 of the (2-2)-th light-blocking pattern BM2-2.

The first line width WD1 and the second line width WD2 may be less than the width of the second pixel-defining layer PDL2. Therefore, light emitted from the (2-1)-th light-emitting element LD2-B in the (2-1)-th light-emitting region PXA-B2 may not be blocked by the first light-blocking pattern BM1 and the second light-blocking pattern BM2.

An organic encapsulation layer 142 may have a thickness D1 greater than a thickness D2 of the first cover layer OC1. On a cross-section, a height difference between the (2-1)-th light-emitting element LD2-B and the first light-blocking pattern BM1 along a third direction DR3 may be less than a height difference between the first light-blocking pattern BM1 and the second light-blocking pattern BM2.

The thickness D1 of the organic encapsulation layer 142 may be about 6 μm to about 12 μm. When the thickness D1 of the organic encapsulation layer 142 is less than about 6 μm, the organic encapsulation layer 142 may be too thin to protect the (2-1)-th light-emitting element LD2-B from external foreign substances. When the thickness D1 of the organic encapsulation layer 142 is greater than about 12 μm, the first light-blocking pattern BM1 may be spaced apart too far from the (2-1)-th light-emitting element LD2-B to prevent leakage of light at a large viewing angle.

The thickness D2 of the first cover layer OC1 may be about 10 μm to about 20 μm. When the thickness D2 of the first cover layer OC1 is less than about 10 μm, the distance between the first light-blocking pattern BM1 and the second light-blocking pattern BM2 may be too close to prevent leakage of light at a large viewing angle. When the thickness D2 of the first cover layer OC1 is greater than about 20 μm, the display device DD, as an entire stacked structure, may be too thick.

FIG. 13 is a cross-sectional view taken along line IV-IV′ of FIGS. 9 and 10 according to an embodiment of the inventive concept. In particular, FIG. 13 is a cross-sectional view taken along line IV-IV′ of FIGS. 9 and 10 in a state where a display panel 100, an input sensor 200, a light control layer 300, and an anti-reflection layer 400 are stacked.

Referring to FIG. 13, at a viewing angle less than or equal to a first viewing angle α1°, light emitted from a (2-1)-th light-emitting element LD2-B may pass through between a (2-1)-th light-blocking pattern BM2-1 and a (2-2)-th light-blocking pattern BM2-2. At this time, the light emitted from the (2-1)-th light-emitting element LD2-B may not be blocked by the first light-blocking pattern BM1 or the second light-blocking pattern BM2, and may thus be viewed to a user. Herein, a viewing angle may be an angle between a pathway of light emitted and the third direction DR3 that is a direction extending perpendicular to the extension direction of a base substrate 110.

Light emitted from the (2-1)-th light-emitting element LD2-B may be blocked by the (1-2)-th light-blocking pattern BM1-2 at a second viewing angle α2°. Herein, the second viewing angle α2° is greater than the first viewing angle α1°. At a viewing angle greater than or equal to the first viewing angle α1°, the light emitted from the (2-1)-th light-emitting element LD2-B of the second region A2 may be blocked by the first light-blocking pattern BM1, and may not be viewed to a user. That is, the first light-blocking pattern BM1 may prevent leakage of the light emitted from the (2-1)-th light-emitting element LD2-B at a large viewing angle.

An organic encapsulation layer 142 may have a thickness D1 greater than a thickness D2 of a first cover layer OC1. Therefore, the first light-blocking pattern BM1 may be positioned close to the (2-1)-th light-emitting element LD2-B while the thickness of the entire display device DD does not change significantly. When the first light-blocking pattern BM1 is positioned close to the (2-1)-th light-emitting element LD2-B, it may be possible to effectively prevent leakage of light at a large viewing angle.

The first line width WD1 may be greater than the second line width WD2. Accordingly, at a viewing angle less than or equal to a predetermined viewing angle, light emitted from the (2-1)-th light-emitting element LD2-B may not be blocked by the first or second light-blocking pattern BM1 or BM2, and at a viewing angle exceeding a predetermined viewing angle, the light may be blocked by the first light-blocking pattern BM1. As previously described, since the first light-blocking pattern BM1 has a large first line width WD1, and the first light-blocking pattern BM1 is positioned close to the (2-1)-th light-emitting element LD2-B, it may be possible to effectively prevent light leakage at a larger viewing angle.

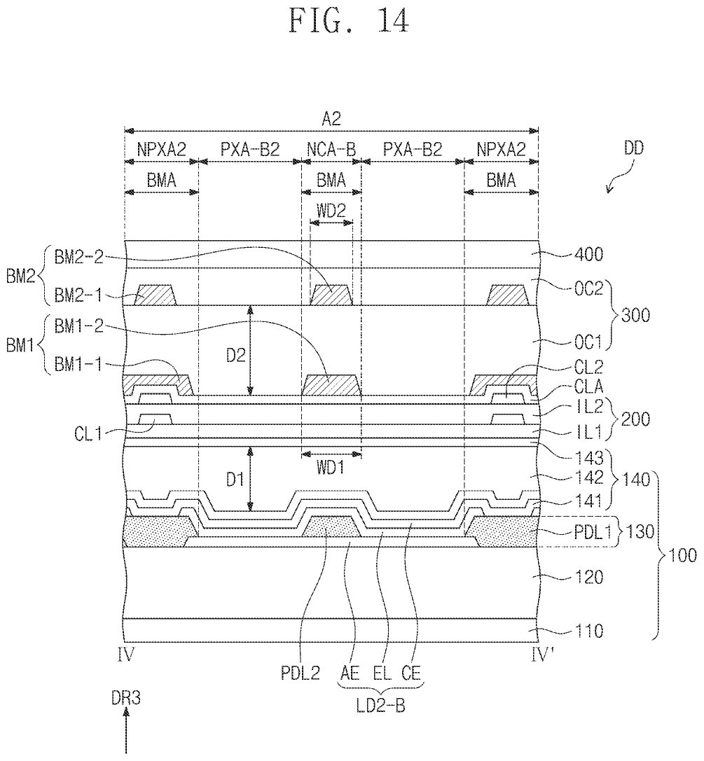

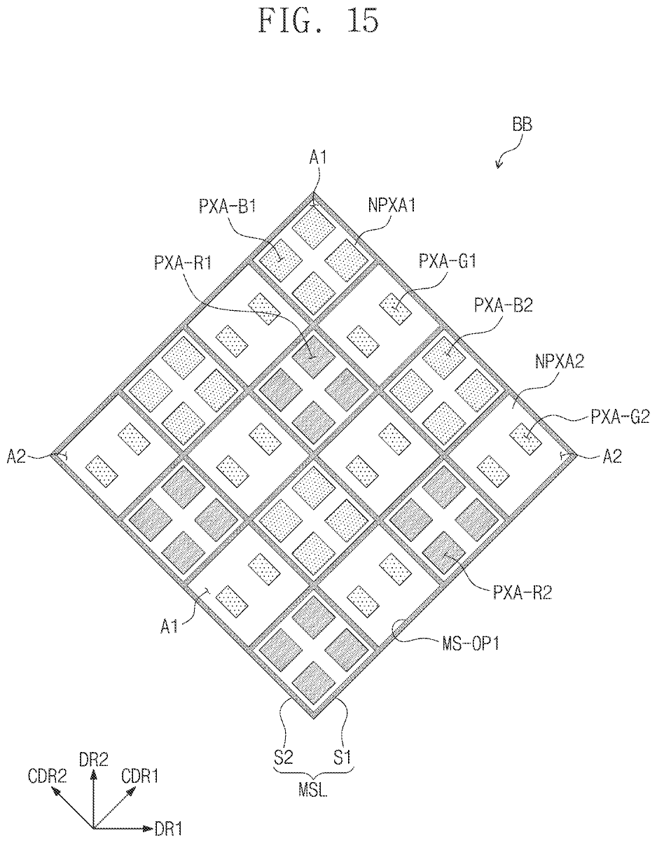

FIG. 14 is a cross-sectional view taken along line IV-IV′ of FIGS. 9 and 10 according to an embodiment of the inventive concept.

Referring to FIG. 14, the display device DD according to this embodiment may further include a protective layer CLA overlapping a second input-sensing electrode CL2. As the configuration except for the protective layer CLA is same as the configuration of the display device DD described with reference to FIG. 12, same reference numerals or symbols are used for the same components, and descriptions thereof will be omitted.

The protective layer CLA may be disposed on a second sensing insulation layer IL2. A portion of the protective layer CLA overlapping a second peripheral region NPXA2 may be disposed between the second input-sensing electrode CL2 and a (1-1)-th light-blocking pattern BM1-1 to cover the second input-sensing electrode CL2. Accordingly, the protective layer CLA may cover the second input-sensing electrode CL2, thereby protecting the second input-sensing electrode CL2 from moisture and oxygen.

The protective layer CLA may include an inorganic material. For example, the protective layer CLA may include a silicon nitride layer, a silicon oxynitride layer, a silicon oxide layer, a titanium oxide layer, an aluminum oxide layer, or the like. However, this is an example, the material of the protective layer CLA is not limited thereto, and the protective layer CLA may include various materials.

FIG. 15 is an enlarged plan view of the region BB of FIG. 7 according to an embodiment of the inventive concept.

Referring to FIG. 15, in each of (1-1)-th light-emitting regions PXA-B1, (1-2)-th light-emitting regions PXA-G1, and (1-3)-th light-emitting regions PXA-R1 disposed in a first region A1, light-emitting regions that provide the same color may be grouped and surrounded by one mesh opening MS-OP1. That is, one mesh opening MS-OP1 may surround four (1-1)-th light-emitting regions PXA-B1, another mesh opening MS-OP1 may surround two (1-2)-th light-emitting regions PXA-G1 of a first group, and another mesh opening MS-OP1 may surround two (1-2)-th light-emitting regions PXA-G1 of a second group, and the remaining one mesh opening MS-OP1 may surround four (1-3)-th light-emitting regions PXA-R1.

The (1-1)-th light-emitting regions PXA-B1 disposed in the first region A1 may have the same arrangement as the (2-1)-th light-emitting regions PXA-B2 disposed in the second region A2. The (1-2)-th light-emitting regions PXA-G1 disposed in the first region A1 may have the same arrangement as the (2-2)-th light-emitting regions PXA-G2 disposed in the second region A2. The (1-3)-th light-emitting regions PXA-R1 disposed in the first region A1 may have the same arrangement as the (2-3)-th light-emitting regions PXA-R2 disposed in the second region A2.

However, the arrangement of each of the (1-1)-th to (1-3)-th light-emitting regions PXA-B1, PXA-G1, and PXA-R1 disposed in the first region A1 is only an example, the number and the arrangement of each of the (1-1)-th to (1-3)-th light-emitting regions PXA-B1, PXA-G1, and PXA-R1 may be changed as needed.

According to the inventive concept, by reducing the thickness of an encapsulation layer to be less than the thickness of the cover layer, and positioning a first light-blocking pattern close to light-emitting elements, a display device capable of preventing leakage of light at a large viewing angle may be provided.

Although the embodiments of the inventive concept have been described, it is understood that the inventive concept should not be limited to these embodiments but various changes and modifications can be made by one ordinary skilled in the art within the spirit and scope of the inventive concept as hereinafter claimed. Therefore, the technical scope of the inventive concept should not be limited to the contents described in the detailed description of the specification, but should be defined by the claims.

What is claimed is:

1. A display device comprising:
first light-emitting elements which are activated in a first operation mode and deactivated in a second operation mode;
second light-emitting elements which are activated in the first operation mode and activated in the second operation mode;
a base substrate including a first region and a second region adjacent to the first region, the first region having a first light-emitting region and a first non-light-emitting region, the first light-emitting elements being disposed in the first light-emitting region, the second region having a second light-emitting region and a second non-light-emitting region, the second light-emitting elements being disposed in the second light-emitting region;
an encapsulation layer disposed on the base substrate and covering the first light-emitting elements and the second light-emitting elements;
at least one insulation layer disposed on the encapsulation layer;
a first light-blocking pattern disposed on the insulation layer, and not overlapping the first region and overlapping the second non-light-emitting region;
a cover layer disposed on the insulation layer and covering the first light-blocking pattern; and
a second light-blocking pattern disposed on the cover layer and overlapping the first light-blocking pattern,
wherein a thickness of the cover layer is greater than a thickness of the encapsulation layer.

2. The display device of claim 1, wherein the thickness of the cover layer is equal to or greater than about 10 μm and equal to or less than about 20 μm.

3. The display device of claim 1, wherein the thickness of the encapsulation layer is equal to or greater than about 6 μm and equal to or less than about 12 μm.

4. The display device of claim 1, further comprising a sensing electrode disposed on the insulation layer, and overlapping the first non-light-emitting region of the first region and the second non-light-emitting region of the second region,
wherein the sensing electrode is disposed on a same layer as the first light-blocking pattern.

5. The display device of claim 4, wherein the first light-blocking pattern covers a portion of the sensing electrode overlapping the second region.

6. The display device of claim 4, further comprising a protective layer disposed on the insulation layer and the sensing electrode, and including an inorganic material,
wherein a portion of the protective layer is disposed between the sensing electrode and the first light-blocking pattern.

7. The display device of claim 1, wherein the second light-emitting region comprises a first element region in which a (2-1)-th light-emitting element configured to provide a first-color light is disposed, a second element region in which a (2-2)-th light-emitting element configured to provide a second-color light is disposed, and a third element region in which a (2-3)-th light-emitting element configured to provide a third-color light is disposed, and
each of the (2-1)-th to (2-3)-th light-emitting elements includes a plurality of sub-light-emitting elements.

8. The display device of claim 7, further comprising a first pixel-defining layer which is disposed on the base substrate, and in which openings are defined,
wherein each of the (2-1)-th to (2-3)-th light-emitting elements includes a first electrode, a second electrode, and a light-emitting layer disposed between the first electrode and the second electrode, and
the openings of the first pixel-defining layer expose at least a portion of the first electrodes of each of the (2-1)-th to (2-3)-th light-emitting elements.

9. The display device of claim 8, further comprising a second pixel-defining layer which is disposed on the first electrodes exposed by the openings, and which overlaps the second non-light-emitting region.

10. The display device of claim 1, wherein at least one of the encapsulation layer and the cover layer comprises an organic material.

11. The display device of claim 1, wherein a first line width of the first light-blocking pattern is greater than a second line width of the second light-blocking pattern.

12. The display device of claim 1, further comprising an anti-reflection layer disposed on the second light-blocking pattern.

13. A display device comprising:
a base substrate including a light-emitting region and a non-light-emitting region;
a light-emitting element disposed on the base substrate;
an organic layer disposed as a single layer on the light-emitting element;
at least one insulation layer disposed on the organic layer;
a first light-blocking pattern disposed on the insulation layer, and overlapping the non-light-emitting region;
a cover layer disposed on the insulation layer, and covering the first light-blocking pattern; and
a second light-blocking pattern disposed on the cover layer and overlapping the first light-blocking pattern,
wherein a thickness of the cover layer is greater than a thickness of the organic layer.

14. The display device of claim 13, wherein the thickness of the cover layer is equal to or greater than about 10 μm and equal to or greater than about 20 μm.

15. The display device of claim 13, wherein the thickness of the organic layer is equal to or greater than about 6 μm to equal to or less than about 12 μm.

16. The display device of claim 13, further comprising a sensing electrode disposed on the insulation layer, and overlapping the non-light-emitting region,
wherein the sensing electrode is disposed on a same layer as the first light-blocking pattern.

17. The display device of claim 16, further comprising a protective layer disposed on the insulation layer and the sensing electrode, and including an inorganic material,
wherein a portion of the protective layer is disposed between the sensing electrode and the first light-blocking pattern.

18. The display device of claim 16, wherein the light-emitting region comprises a first element region in which a first light-emitting element configured to provide a first-color light is disposed, a second element region in which a second light-emitting element configured to provide a second-color light is disposed, and a third element region in which a third light-emitting element configured to provide a third-color light is disposed,
each of the first to third light-emitting elements includes a plurality of sub-light-emitting elements.

19. The display device of claim 16, wherein the first light-blocking pattern is in contact with the sensing electrode.

20. The display device of claim 13, wherein the organic layer and the cover layer each comprise an organic material.
